(19) United States
(12) Patent Application Publication
(10) Pub. No.: US 2019/0276128 A1
(43) Pub. Date: Sep. 12, 2019

(54) UNMANNED AERIAL VEHICLE FUSELAGE

(71) Applicant: Vortex Labs Inc., Waterloo (CA)

(72) Inventors: James Thomas Pike, Waterloo (CA); David Giessel, Cambridge (CA); Bruce Hildesheim, Cambridge (CA)

(73) Assignee: Vortex Labs Inc., Waterloo (CA)

(21) Appl. No.: 16/295,288

(22) Filed: Mar. 7, 2019

Related U.S. Application Data
(60) Provisional application No. 62/639,972, filed on Mar. 7, 2018.

(51) Int. Cl. B64C 1/06; B64C 39/02; B64C 27/32; H05K 5/00; H05K 1/18

(52) U.S. Cl. CPC B64C 1/062; B64C 39/024; B64C 27/32; H05K 5/0026; H01R 12/7088; B64C 2201/027; B64C 2201/108; B64C 2201/165; H05K 1/182

(57) ABSTRACT

Implementations of an unmanned aerial vehicle (UAV) fuselage are provided. In some implementations, the fuselage comprises a frame having a shell removably secured thereto. The frame of the fuselage is made of printed circuit board (PCB) material that includes conductive tracks configured to conductively connect electrical components of the UAV. Due to the inherent rigidity of PCB material, the transfer of vibration loads to electrical components secured to the frame of the fuselage is minimized. While the shell is secured to the frame, an enclosure for any electrical components on the topside of the frame is formed. In this way, the encased electrical components may be protected from the environment (e.g., rain) and direct impact during a crash. In some implementations, the frame of the UAV fuselage may include a plurality of stiffening inserts that are positioned and configured to increase the rigidity of the frame.

### CROSS REFERENCE TO RELATED APPLICATION

This application claims the benefit of U.S. Provisional Application Ser. No. 62/639,972, which was filed on Mar. 7, 2018, the entirety of which is incorporated herein by reference.

### TECHNICAL FIELD

This disclosure relates to implementations of an unmanned aerial vehicle (UAV) fuselage.

### BACKGROUND

An unmanned aerial vehicle (UAV), also known as a drone, is an aircraft without a human pilot aboard. UAV's are a component of an unmanned aircraft system (UAS) which includes a UAV and a ground-based controller that are connected by a two-way communication system. UAVs are often equipped with cameras, infrared devices, and other equipment according to its intended use, for example, surveillance, communication/information broadcasting, etc.

Unmanned aerial vehicles (UAVs) are at constant risk of hard landings, collisions, and crashes. Often, the fuselage of a UAV, or an electronic device mounted on the fuselage, is damaged during one of those events. As its quite expensive to replace a UAV, its beneficial to configure a UAV so that its better able to survive a hard landing, collision, or crash.

Radius of action is the maximum distance that a UAV can travel from its base with any payload(s) required to complete its intended task, and return to base without refreshing its power supply. Endurance (or flight time) within the radius of action is an important consideration when designing a UAV and is a function of its weight, aerodynamics, and available power supply. Therefore, reducing the weight of a UAV is an effective way to increase endurance within its radius of action.

Under routine flight conditions, electrical components of a UAV are often subjected to torsional and/or compressive forces. These forces can reduce the service life of affect electrical components and/or disrupt the proper function thereof.

Accordingly, it can be seen that needs exist for the unmanned aerial vehicle fuselage disclosed herein. It is to the provision of an unmanned aerial vehicle fuselage that is configured to address these needs, and others, that the present invention is primarily directed.

### SUMMARY OF THE INVENTION

Implementations of an unmanned aerial vehicle (UAV) fuselage are provided. In some implementations, the fuselage may be configured to minimize the transfer of vibration loads to electrical components secured thereto (e.g., a flight controller, motor controllers, a radio module, a GPS, a payload device, etc.). In this way, any disruption to the function of an electrical component sensitive to vibration loads is minimized or eliminated. In some implementations, the fuselage may be configured to encase one or more electrical components adapted to control the operation of a UAV. In this way, the encased electrical components may be protected from the environment (e.g., rain) and/or from direct impact should the UAV crash.

An unmanned aerial vehicle (UAV) having a fuselage constructed in accordance with the principles of the present disclosure may comprise a first motor arm assembly and a second motor arm assembly detachably secured to the fuselage, each motor arm assembly may be detachably secured to the fuselage by two mechanical connectors and comprises a tube having a rotary wing propulsion system on each end thereof. In some implementations, each motor arm assembly further comprises an electrical connector positioned between the two rotary wing propulsion systems thereon that is configured to conductively interface with an electrical connector in the underside of the fuselage. In this way, each rotary wing propulsion system may be conductively connected to one or more electrical components of the UAV.

In some implementations, the fuselage may comprise a frame having a shell removably secured thereto, the frame may also include two mounting rails that are removably secured to the underside thereof. The mounting rails are configured so that a power source (e.g., one or more batteries) and/or a payload device (e.g., a video camera, a thermal imager, a radio relay, a portable cellular tower, or a combination of these devices) can be removably secured to the underside of the fuselage. In some implementations, the underside of the fuselage may further comprise an electrical connector configured to conductively interface with a power source and/or an electrical connector configured to conductively interface with a payload device secured to the fuselage by the mounting rails. In this way, a power source and/or a payload device can be conductively connected to the other electrical components of the UAV.

In some implementations, the shell can be secured to the frame of the fuselage and thereby form an enclosure for any electrical components secured to, or extending from, the topside of the frame (e.g., a flight controller, motor controllers, a radio module, GPS, etc.). In this way, the encased electrical components may be protected from the environment (e.g., rain) and/or from direct impact during a crash.

In some implementations, the frame of the fuselage is made of printed circuit board (PCB) material (e.g., FR4 glass-reinforced epoxy laminate material). In such implementations, the frame of the fuselage includes conductive tracks printed onto the one or more layers of material (non-conductive substrate) that make up the frame, the conductive tracks are configured to conductively connect the electrical components of the UAV (e.g., the flight controller, motor controllers, radio module, GPS, power source, payload device, etc.).

By constructing the frame of the UAV fuselage from PCB material, the overall weight of the UAV is reduced by replacing copper wires, or other conductive wires, with the conductive tracks of the PCB material. In some implementations, the conductive tracks of the PCB material from which the frame is made may have identical, or nearly identical, geometry, be stacked directly on top of each other, and/or have minimal separation therebetween (e.g., separation by an insulating layer of substrate material). In this way, by using conductive tracks in-lieu of conductive wires, a magnetic field normally generated while electrical current is being drawn from a power source by a conductively connected electrical component may be reduced.

In some implementations, the frame and the shell of the UAV fuselage may be placed under tension and compression, respectively, due to the upward forces placed against the underside of the frame during flight by the motor arm assemblies positioned adjacent opposite ends thereof. In some implementations, using a frame made from a PCB material and securing the motor arm assemblies to the underside of the frame contributes to the overall rigidity of the UAV fuselage. In this way, vibrations generated during the normal operation of a UAV may be reduced. Further, by placing the frame of the UAV fuselage under tension, any torsional or compressive forces that the electrical components, mounted on the frame, may be subjected to during the operation of the UAV are minimized or eliminated. In this way, the service life and/or reliability of the electrical components mounted on the frame may be increased.

In some implementations, the frame of the UAV fuselage may include a plurality of stiffening inserts positioned and configured to receive fasteners used to secure the shell thereto. In this way, the shell and the frame of the fuselage may be mechanically secured together. Further, in some implementations, the stiffening inserts may be positioned and configured (e.g., shaped) to increase the rigidity of the frame. In some implementation, each stiffening insert may comprise a body portion having a flange on a first end thereof, the flange may be positioned to rest against the underside of the frame while the body portion extends through the frame and from the topside thereof.

In some implementations, the frame and the shell of the UAV fuselage may be placed under tension and compression, respectively, due to the upward forces placed against the underside of the frame during flight by the motor arm assemblies positioned adjacent opposite ends thereof. In some implementations, using a frame made from a PCB material and securing the motor arm assemblies to the underside of the frame contributes to the overall rigidity of the fuselage. In this way, vibrations generated during the normal operation of a UAV may be reduced. Further, by placing the frame of the UAV fuselage under tension, any torsional or compressive forces that the electrical components, mounted on the frame, may be subjected to during the operation of the UAV are minimized or eliminated. In this way, the service life and/or reliability of the electrical components mounted on the frame may be increased. Further still, due to the rigidity of the fuselage, the responsiveness of the UAV to wind gusts and/or control inputs is increased.

In some implementations, one or more layers of the frame may include one or more copper pours therein. Copper pours positioned in adjacent layers of the PCB material may be connected by one or more vias and thereby wick heat away from the interior of the fuselage. In some implementations, the copper pours are positioned on the frame of the fuselage in spaces that do not have an electrical component mounted thereon or conductive tracks therein.

### BRIEF DESCRIPTION OF THE DRAWINGS

FIG. 1 illustrates an unmanned aerial vehicle (UAV) having a fuselage constructed in accordance with the principles of the present disclosure.

FIGS. 2A and 2B illustrate the fuselage of the UAV shown in FIG. 1.

FIG. 3A illustrates an exploded view of the UAV fuselage shown in FIGS. 2A and 2B.

FIG. 3B illustrates a detailed view of the UAV fuselage shown in FIG. 3A.

FIG. 3C illustrates another exploded view of the UAV fuselage shown in FIGS. 2A and 2B.

Like reference numerals refer to corresponding parts throughout the several views of the drawings.

### DETAILED DESCRIPTION

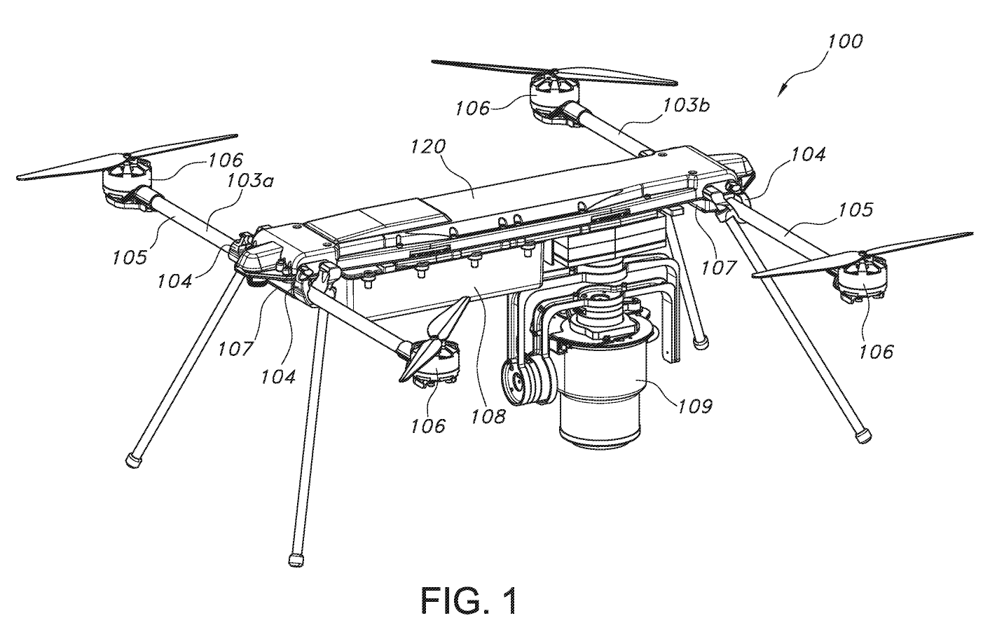

FIG. 1 illustrates an unmanned aerial vehicle (UAV) 100 having a fuselage 120 constructed in accordance with the principles of the present disclosure. In some implementations, the UAV fuselage 120 may be configured to minimize the transfer of vibration loads to electrical components secured thereto (e.g., a flight controller 110, motor controllers 112, a radio module 114, a Global Positioning System 116, a payload device 109, etc.). In this way, any disruption to the function of an electrical component sensitive to vibration loads (e.g., a sensor, a payload device, etc.) is minimized or eliminated. In some implementations, the UAV fuselage 120 may be configured to encase one or more electrical components adapted to control the operation of the UAV 100. In this way, the encased electrical components may be protected from the environment (e.g., rain) and/or from direct impact should the UAV 100 crash into the ground or another object.

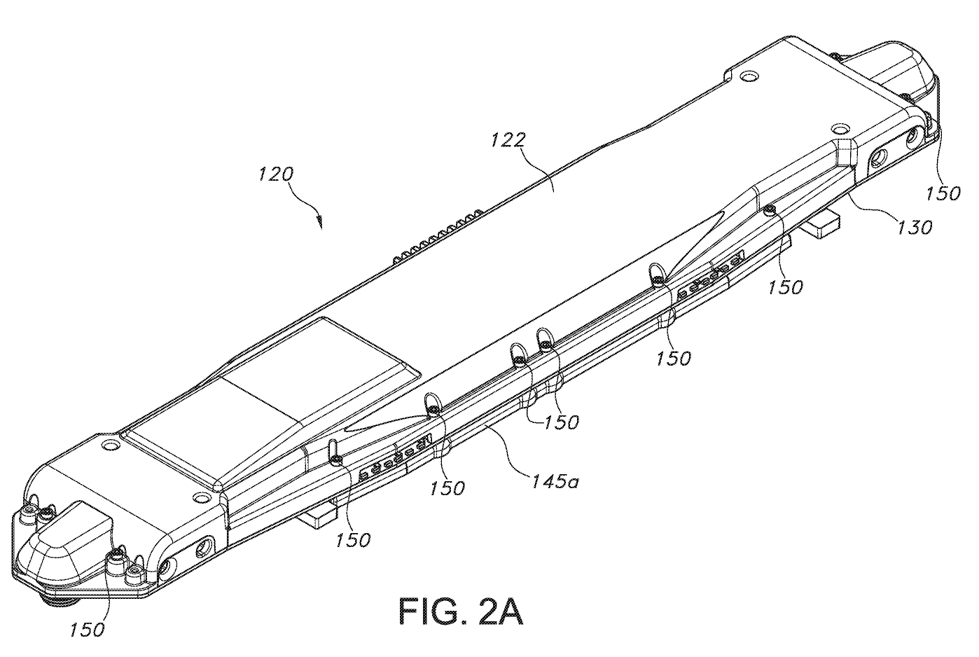

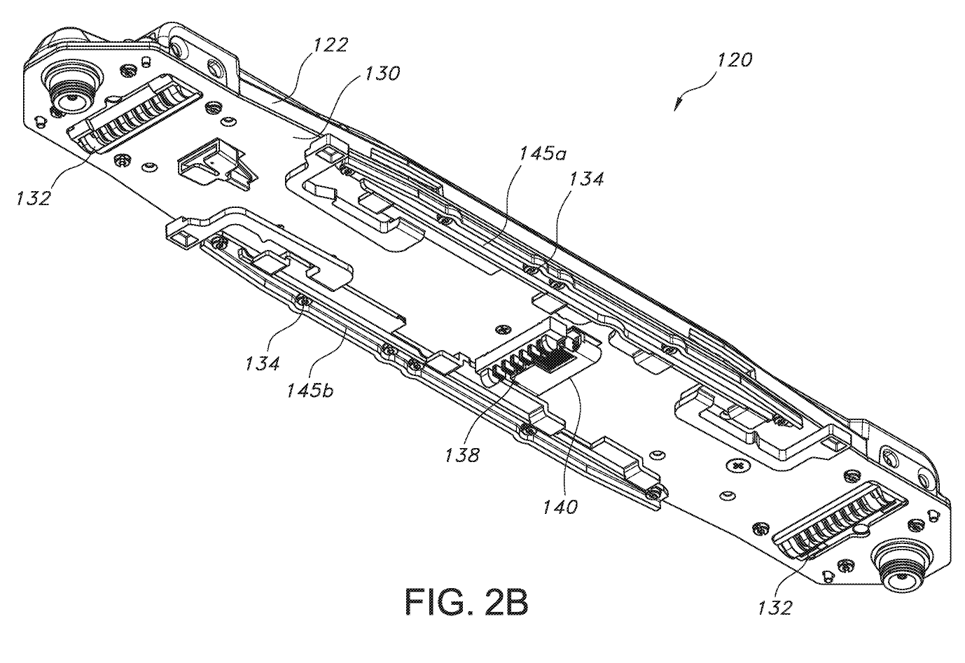

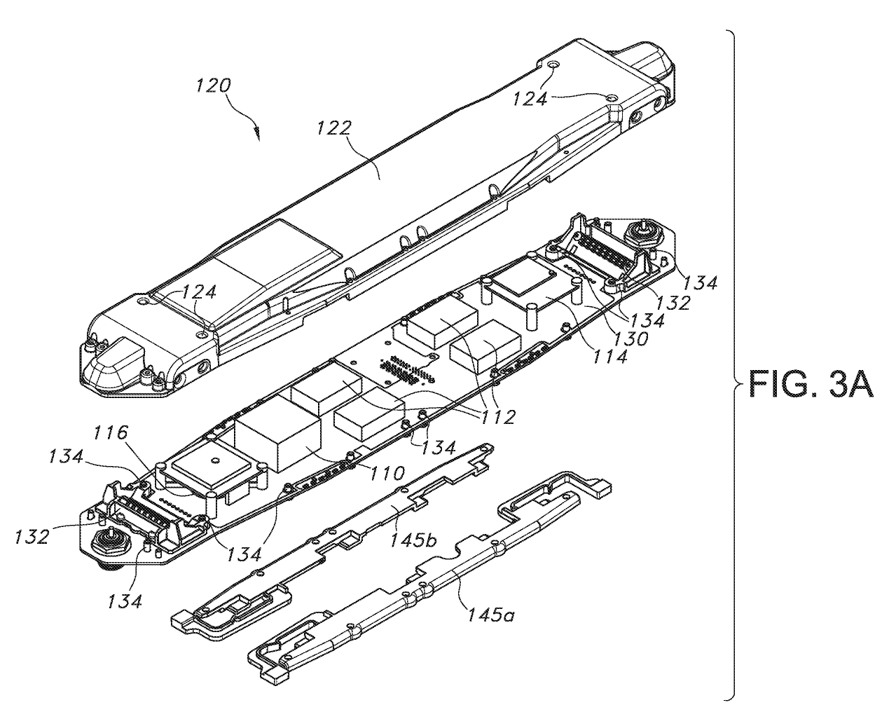

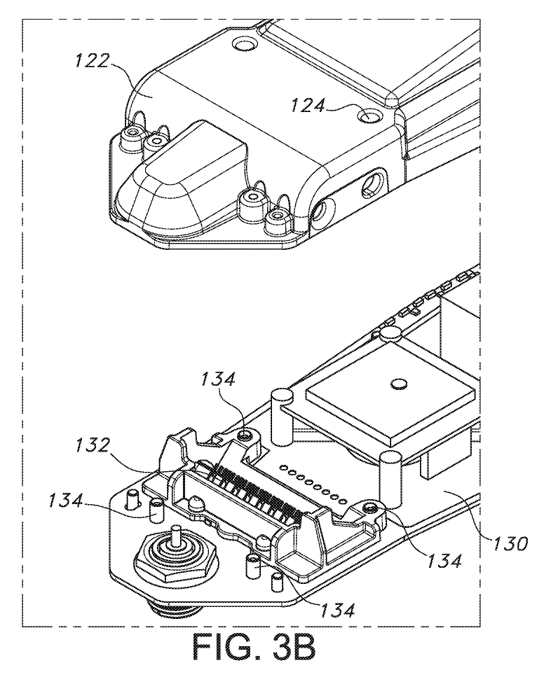

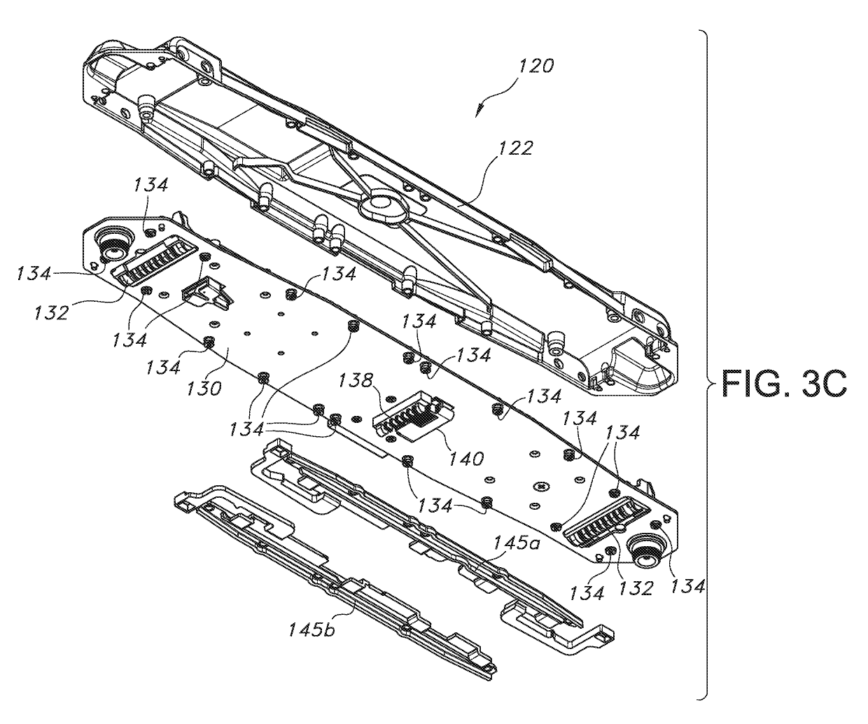

As shown in FIG. 1, in some implementations, an example UAV 100 may comprise a fuselage 120 having a first motor arm assembly 103a and a second motor arm assembly 103b (collectively motor arms 103) detachably secured thereto, each motor arm assembly 103a, 103b may be detachably secured to the fuselage 120 by two mechanical connectors 104 and comprises a tube 105 having a rotary wing propulsion system 106 on each end thereof. In some implementations, each mechanical connector 104 may be the same as, or similar to, a mechanical connector described in U.S. patent application Ser. No. 16/285,614, filed on Feb. 26, 2019, entitled “UNMANNED AERIAL VEHICLE PROVIDED WITH DETACHABLE MOTOR ARMS”, by James Thomas Pike (hereinafter, “the Pike application”), which is also owned by the applicant of the present application and is hereby expressly incorporated by reference as if fully set forth herein. In some implementations, each motor arm assembly 103a, 103b further comprises an electrical connector 107 positioned between the two rotary wing propulsion systems 106 thereon that is configured to conductively interface with an electrical connector 132 in the underside of the fuselage 120 (see, e.g., FIGS. 2B and 3C). In this way, each rotary wing propulsion system 106 may be conductively connected to the electrical components of the UAV 100 (e.g., the power source 108, control system(s) (e.g., elements 110 and/or 112), the radio module 114, or a combination thereof). One of ordinary skill in the art would know how to select an appropriate rotary wing propulsion system for the UAV 100 disclosed herein.

As shown in FIG. 1, in some implementations, the UAV fuselage 120 may be configured so that a power source 108 (e.g., one or more batteries) and/or a payload device 109 (e.g., a video camera, a thermal imager, a radio relay, a portable cellular tower, or a combination of these devices) can be removably secured to the underside thereof and be conductively connected to other electrical components of the UAV 100.

As shown in FIGS. 2A-2B and 3A-3C, in some implementations, the UAV fuselage 120 may comprise a frame 130 having a shell 122 removably secured thereto, the frame 130 may also include two mounting rails 145a, 145b that are removably secured to the underside thereof.

As shown in FIGS. 2A and 2B, in some implementations, the shell 122 can be secured to the frame 130 of the UAV fuselage 120 and thereby form an enclosure for the electrical components (e.g., the flight controller 110, motor controllers 112, radio module 114, GPS 116, etc.) secured to, or extending from, the topside of the frame 122. In this way, the encased electrical components may be protected from the environment (e.g., rain) and/or from direct impact should the UAV 100 crash into the ground or another object. In some implementations, the shell 122 may be secured to the frame 130 of the UAV fuselage 120 by one or more fasteners 150 (e.g., screws). In this way, the UAV fuselage 120 may be easily assembled and/or disassembled. In some implementations, each fastener can be inserted through an opening 124 in the shell 122 of the UAV fuselage 120 and threadedly received in a corresponding opening of a stiffening insert 134 (discussed in greater detail below) in the frame 130 (see, e.g., FIG. 3A).

In some implementations, the shell 122 may be secured to the frame 130 of the UAV fuselage 120 by an adhesive, or any other suitable fastener known to one of ordinary skill in the art (not shown).

As shown in FIGS. 3A-3C, in some implementations, the frame 130 of the UAV fuselage 130 may be made of printed circuit board (PCB) material (e.g., FR4 glass-reinforced epoxy laminate material). In such implementations, the frame 130 of the UAV fuselage 120 may include conductive tracks printed onto the one or more layers of material (non-conductive substrate) that make up the frame 130, the conductive tracks are configured to conductively connect electrical components of the UAV 100 (e.g., the flight controller 110, motor controllers 112, radio module 114, GPS 116, power source 108, payload device 109, etc.). For example, in some implementations, the conductive tracks may conductively connect the power source 108 to an electrical connector 132 and thereby the propulsion system(s) 106 of a motor arm assembly 103a, 130b.

In some implementations, by constructing the frame 130 of the UAV fuselage 120 from PCB material, the overall weight of the UAV 100 is reduced by replacing copper wires, or other conductive wires, with the conductive tracks of the PCB material. Further, constructing the frame 130 from PCB material removes the need to position a cover, or shell, over the underside thereof.

In some implementations, the conductive tracks of the PCB material from which the frame 130 is made may have identical, or nearly identical, geometry, be stacked directly on top of each other, have minimal separation therebetween (e.g., separation by an insulating layer of substrate material), or a combination thereof. In this way, by using conductive tracks in-lieu of conductive wires, a magnetic field normally generated while electrical current is being drawn from the power source 108 by a conductively connected electrical component may be reduced. In some implementations, a magnetic field generated by electrical current being drawn from a power source (e.g., power source 108) may be reduced by minimizing the loop area between the conductive tracks used to complete the supply path(s) and the return path(s) of the power source and one or more other conductively connected electrical components mounted to the frame 130 of the UAV 100. In this way, any disruption to the function of electrical components sensitive to magnetic fields is minimized or eliminated (e.g., a sensor of the GPS 116 or the flight controller 110.

In some implementations, due to the rigidity inherent to PCB material, the transfer of vibration loads to electrical components secured to the frame 130 of the UAV fuselage 120 is minimized. In this way, any disruption to the function of electrical components (e.g., a sensor of the GPS 116, a payload device 109, etc.) sensitive to vibration loads is minimized or eliminated.

As shown in FIGS. 3A-3C, in some implementations, the frame 130 of the UAV fuselage 120 may include a plurality of stiffening inserts 134 positioned and configured to receive the threaded fasteners 150 used to secure the shell 122 thereto. In this way, the shell 122 and the frame 130 of the UAV fuselage 120 may be mechanically secured together. Further, in some implementations, the stiffening inserts 134 may be positioned and configured (e.g., shaped) to increase the rigidity of the frame 130. In some implementation, each stiffening insert 134 may comprise a body portion having a flange on a first end thereof, the flange may be positioned to rest against the underside of the frame 130 (see, e.g., FIG. 3C) while the body portion extends through the frame 130 and from the topside thereof (see, e.g., FIG. 3A). In some implementations, the body portion of each stiffening insert 134 includes a threaded interior opening into which a threaded fastener 150 may be secured (see, e.g., FIG. 3B). In some implementations, the frame 130 of the UAV fuselage 120 may include more than twenty, or less than twenty, stiffening inserts 134. In some implementations, each stiffening insert 134 may be aluminum, or another suitable stiff, lightweight material.

As shown in FIG. 1, in some implementations, the mounting rails 145a, 145b secured to the underside of the frame 130 may be configured to facilitate the attachment of a power source 108 and/or a payload device (e.g., the camera 109) to the underside of the UAV 100. In some implementations, each mounting rail 145a, 145b may be secured to the underside of the UAV frame 130 by one or more fasteners 150 (e.g., screws) used in conjunction with a stiffening insert 134 (see, e.g., FIGS. 2A and 2B). In some implementations, while secured to the underside of the fuselage 120, the mounting rails 145a, 145b provide additional structural stiffness and strength.

As shown in FIGS. 2B and 3C, in some implementations, the underside of the UAV fuselage 120 may include an electrical connector 138 configured to conductively interface with the power source 108 and/or an electrical connector 140 configured to conductively interface with a payload device 109 (see, e.g., FIG. 2B).

As shown in FIG. 1, in some implementations, the frame 130 and the shell 122 of the UAV fuselage 120 may be placed under tension and compression, respectively, due to the upward forces placed against the underside of the frame 130 during flight by the motor arm assemblies 103a, 103b positioned adjacent opposite ends thereof. In some implementations, using a frame 130 made from a PCB material and securing the motor arm assemblies 103a, 103b to the underside of the frame 120 contributes to the overall rigidity of the UAV fuselage 120. In this way, vibrations generated during the normal operation of a UAV 100 may be reduced. Further, by placing the frame 130 of the UAV fuselage 120 under tension, any torsional or compressive forces that the electrical components, mounted on the frame 130, may be subjected to during the operation of the UAV 100 are minimized or eliminated. In this way, the service life and/or reliability of the electrical components mounted on the frame 130 may be increased. Further still, due to the rigidity of the fuselage 120, the responsiveness of the UAV 100 to wind gusts and/or control inputs is increased.

Although not shown in the drawings, it will be understood that suitable wiring, or traces, connect each propulsion system 106 to the electrical connector 107 of a motor arm assembly 103a, 103b and thereby to one or more of the electrical components secured to the frame 130 of the UAV fuselage 120.

In some implementations, through the use of copper pours, the UAV fuselage 120 may be configured to wick heat away from the interior thereof. In some implementations, one or more layers of the UAV frame 130 may include one or more copper pours therein, copper pours positioned in adjacent layers of the PCB material may be connected by one or more vias and thereby wick heat away from the interior of the UAV fuselage 120. In some implementations, the copper pours are positioned on the frame 130 of the UAV fuselage 120 in spaces that do not have an electrical component mounted thereon or conductive tracks therein. In some implementations, the one or more copper pours of the UAV frame 130 may serve as a ground plane for the GPS 116. In some implementations, the one or more copper pours of the UAV frame 130 may shield the electrical components positioned within the interior of the UAV fuselage 120 against radio frequency interference. In some implementations, the one or more copper pours of the UAV frame 130 may shield the electrical components positioned within the interior of the UAV fuselage 120 from any electric field(s) generated by the power source 108 and/or the payload device 109. In some implementations, the PCB material of the UAV frame 130 may not include one or more copper pours therein.

Fasteners 150 used to secure the shell 122 and/or the mounting rails 145a, 145b to the frame 130 of the fuselage 120 have been omitted from some figures for clarity.

Reference throughout this specification to “an embodiment” or “implementation” or words of similar import means that a particular described feature, structure, or characteristic is included in at least one embodiment of the present invention. Thus, the phrase “in some implementations” or a phrase of similar import in various places throughout this specification does not necessarily refer to the same embodiment.

Many modifications and other embodiments of the inventions set forth herein will come to mind to one skilled in the art to which these inventions pertain having the benefit of the teachings presented in the foregoing descriptions and the associated drawings.

The described features, structures, or characteristics may be combined in any suitable manner in one or more embodiments. In the above description, numerous specific details are provided for a thorough understanding of embodiments of the invention. One skilled in the relevant art will recognize, however, that embodiments of the invention can be practiced without one or more of the specific details, or with other methods, components, materials, etc. In other instances, well-known structures, materials, or operations may not be shown or described in detail.

While operations are depicted in the drawings in a particular order, this should not be understood as requiring that such operations be performed in the particular order shown or in sequential order, or that all illustrated operations be performed, to achieve desirable results.

1. An unmanned aerial vehicle comprising:
a fuselage that has a first motor arm and a second motor arm detachably secured thereto, each motor arm is detachably secured to the fuselage by two mechanical connectors and comprises a tube having a rotary wing propulsion system on each end thereof;
wherein:
the fuselage comprises a frame and a shell that form an enclosure;
the frame is made of a printed circuit board material; and
the printed circuit board material comprises at least one layer of a non-conductive substrate that includes conductive tracks thereon.

2. The unmanned aerial vehicle of claim 1, wherein the frame of the fuselage includes a plurality of stiffening inserts that are positioned and configured to increase the rigidity of the frame.

3. The unmanned aerial vehicle of claim 2, wherein each stiffening element comprises a body portion having a flange on a first end thereof, the flange rest against an underside of the frame and the body portion extends through the frame.

4. The unmanned aerial vehicle of claim 4, wherein the shell is secured to the frame by fasteners, each fastener extends through an opening in the shell and is secured to a corresponding stiffening insert in the frame of the fuselage.

5. The unmanned aerial vehicle of claim 1, wherein the fuselage further comprises two mounting rails secured to the underside of the frame, the mounting rails are configured so that at least one payload device can be secured to the underside of the fuselage.

6. The unmanned aerial vehicle of claim 5, wherein the underside of the frame of the fuselage further comprises an electrical connector configured to conductively interface with a payload device secured to the underside of the fuselage by the mounting rails.

7. The unmanned aerial vehicle of claim 1, wherein the fuselage is elongated.

8. The unmanned aerial vehicle of claim 1, wherein each motor arm further comprises an electrical connector positioned between the two rotary wing propulsion systems thereon that is configured to conductively interface with an electrical connector in an underside of the fuselage.

9. The unmanned aerial vehicle of claim 1, wherein the frame of the fuselage includes at least one copper pour that is positioned in the printed circuit board material thereof, the copper pour is configured to wick heat away from the interior of the enclosure formed by the fuselage.

10. A fuselage of an unmanned aerial vehicle, the fuselage comprising:
a frame and a shell that form an enclosure, the frame is made of a printed circuit board material, and the printed circuit board material comprises at least one layer of a non-conductive substrate that includes conductive tracks thereon.

11. The fuselage of claim 10, wherein the frame of the fuselage includes a plurality of stiffening inserts that are positioned and configured to increase the rigidity of the frame.

12. The fuselage of claim 11, wherein each stiffening element comprises a body portion having a flange on a first end thereof, the flange rest against an underside of the frame and the body portion extends through the frame.

13. The fuselage of claim 12, wherein the shell is secured to the frame by fasteners, each fastener extends through an opening in the shell and is secured to a corresponding stiffening insert in the frame of the fuselage.

14. The fuselage of claim 10, wherein the fuselage further comprises two mounting rails secured to the underside of the frame, the mounting rails are configured so that at least one payload device can be secured to the underside of the fuselage.

15. The unmanned aerial vehicle of claim 14, wherein the underside of the frame of the fuselage further comprises an electrical connector configured to conductively interface with a payload device secured to the underside of the fuselage by the mounting rails.

16. The unmanned aerial vehicle of claim 10, wherein the fuselage is elongated.

17. The unmanned aerial vehicle of claim 10, wherein the frame of the fuselage includes at least one copper pour that is positioned in the printed circuit board material thereof, the copper pour is configured to wick heat away from the interior of the enclosure of the fuselage.
